(19) United States
(12) Patent Application Publication
(10) Pub. No.: US 2018/0348869 A1
(43) Pub. Date: Dec. 6, 2018

(54) OPERATOR APPARATUS FOR A MOTOR VEHICLE WITH DRIVE DEVICE FOR OUTPUTTING A HAPTIC FEEDBACK, AND MOTOR VEHICLE

(71) Applicant: VALEO Schalter und Sensoren GmbH, Bietigheim-Bissingen (DE)

(72) Inventors: Joachim Hentschel, Bad Rodach (DE); Martin Schmitt, Bad Rodach (DE)

(73) Assignee: VALEO Schalter und Sensoren GmbH, Bietigheim-Bissingen (DE)

(21) Appl. No.: 15/778,809

(22) PCT Filed: Nov. 18, 2016
(86) PCT No.: PCT/EP2016/078171

§ 371 Date: May 24, 2018

(30) Foreign Application Priority Data
Nov. 27, 2015 (DE) 10 2015 120 605.6

(51) Int. Cl. G06F 3/01; G06F 3/041; B60Q 9/00; B06B 1/04

(52) U.S. Cl. CPC G06F 3/016; G06F 3/041; B60K 37/06; B06B 1/045; B60Q 9/00

(57) ABSTRACT

The invention relates to an operator apparatus (3) for a motor vehicle (1), with an operator element (4), with a capture device (5) for capturing an operator input carried out on the operator element (4), and with a drive device (6), by means of which the operator element (4) can be moved, in a manner depending on the operator input captured with the capture device (5), for the purpose of outputting a haptic feedback, wherein the drive device (6) exhibits an electromagnet (17) and a motion element (19) which can be moved by an activation of the electromagnet (17), wherein the electromagnet (17) and the motion element (19) are arranged relative to one another in such a manner that a predetermined spacing continues to exist between the electromagnet (17) and the motion element (19) when the motion element is moved (19).

The present invention relates to an operator apparatus for a motor vehicle, with an operator element, with a capture device for capturing an operator input carried out on the operator element, and with a drive device, by means of which the operator element can be moved, in a manner depending on the operator input captured with the capture device, for the purpose of outputting a haptic feedback, wherein the drive device exhibits an electromagnet and a motion element which can be moved by the activation of the electromagnet. In addition, the present invention relates to a motor vehicle with such an operator apparatus.

In the present case, interest is directed, in particular, to operator apparatuses for motor vehicles. Operator apparatuses of such a type are known in various embodiments from the state of the art. Such operator apparatuses ordinarily include an operator element which can be actuated for the purpose of carrying out an operator action. This actuation may, for instance, be undertaken with at least one finger or with an appropriate input unit. The operator input can be captured with an appropriate capture device. In consequence of the captured operator action, a corresponding control signal can be output, with which a functional device, assigned to the operator apparatus, of the motor vehicle can be activated. Such a functional device may be, for instance, an infotainment system, a navigation system, an air-conditioning unit or such like.

In addition, operator apparatuses that exhibit a drive device are known from the state of the art. When a contact with or actuation of the operator element is detected with the capture device, a haptic feedback can be output with this drive device. In this way, the operator action can be virtually acknowledged by the haptic feedback. For the purpose of outputting the haptic feedback, the operator element can be caused to execute mechanical oscillations by means of the drive device. These oscillations can then be transmitted to the at least one finger of the operator.

In this connection, WO 2013/034507 A2 describes an operator device for an electrical instrument, with an actuating element with haptic feedback, which exhibits a touch-sensitive operator interface, wherein the actuating element can be actuated by an operator by means of an input member, and an actuating signal can be triggered, and wherein the actuating element is supported so as to be capable of swivelling about a swivel axis between a rest position and a switching position. In this case there is provision that by virtue of the actuating signal an electromagnetic actuator for generating a magnetic field can be activated, by which a rotationally supported element that can be influenced magnetically can be moved from an initial position into a swivelling position, wherein, by virtue of the motion of the element that can be influenced magnetically, a torque that is capable of moving the actuating element out of the rest position into the switching position can act upon the actuating element directly or indirectly.

In addition, DE 10 2009 007 243 B4 describes a haptic operator device for motor vehicles. The operator device includes at least one touch-sensitive touch-region, wherein in the event of a contact with the touch-region a switching signal can be triggered and the touch-field can be movably driven in a defined rhythm in the plane of the touch-field by an armature, coupled with the touch-field, of a magnetic-motion drive. In this case there is provision that the magnetic-motion drive exhibits a hinged-armature magnet, with an iron core enclosed by a coil, and an armature plate which is supported so as to be capable of swivelling about a swivel axis and which is coupled with the touch-field.

In addition, US 2015/0002279 A1 describes a magnet with which a haptic feedback can be output. The magnet includes a fixed element, which includes a coil, and a mobile element, which is connected to an indicating element. When the coil is energized, the mobile element is moved in the direction of the fixed element, so that the mobile element is linked with the fixed element and consequently a magnetic circuit has been closed.

It is an object of the present invention to demonstrate a solution as to how an operator apparatus with a drive device that exhibits an electromagnet can be operated more efficiently.

In accordance with the invention, this object is achieved by an operator apparatus and also by a motor vehicle with the features according to the respective independent claims. Advantageous further developments of the present invention are the subject-matter of the dependent claims, of the description and of the figures.

An operator apparatus according to the invention for a motor vehicle includes an operator element. In addition, the operator apparatus includes a capture device for capturing an operator input carried out on the operator element. Furthermore, the operator apparatus includes a drive device, by means of which the operator element can be moved, in a manner depending on the operator input captured with the capture device, for the purpose of outputting a haptic feedback. In this connection the drive device exhibits an electromagnet and a motion element which can be moved by an activation of the electromagnet. In this connection, the electromagnet and the motion element are arranged in such a manner relative to one another that a predetermined spacing continues to exist between the electromagnet and the motion element when the motion element is moved.

The operator apparatus can be employed in a motor vehicle. The operator apparatus may have been arranged in a passenger compartment of the motor vehicle, for instance in the centre console or in the instrument panel. The operator apparatus includes the operator element which, for instance, can be operated by the driver of the motor vehicle or by a further occupant of the motor vehicle. For the purpose of carrying out the operator action, in the course of which the operator element is operated, the occupant of the vehicle may, for instance, press on the operator element or touch it with at least one finger or with an appropriate input unit. With the aid of the capture device of the operator apparatus, this touching—or, to be more exact, the operator action—can be captured. The capture device may, for instance, exhibit a touch-sensitive sensor element, with which the touching of the operator interface can be detected. With the aid of the capture device, in addition the position at which the operator element is touched can be captured. In a manner depending on the operator action captured with the capture device, a corresponding control signal can then be output and transmitted to the drive device.

With the aid of the drive device, the operator element can be moved. In particular, the operator element can be caused to execute mechanical oscillations or vibrations with the aid of the drive device. In this way, a haptic feedback can be output to the operator or to the occupant of the vehicle who is currently touching the operator element. In this connection there is provision that the drive device includes an electromagnet and a motion element. By the activation of the electromagnet, the motion element can be moved. For the purpose of activating the electromagnet, the electromagnet or a coil of the electromagnet can have electric current applied to it. A magnetic field is then generated by the electromagnet, by which the motion element is moved. By virtue of the motion of the motion element, the operator element is then moved or excited to execute oscillations.

The motion element may have been formed at least partly from a magnetisable material. For instance, the motion element may have been formed at least partly from a ferromagnetic material, for instance a metal. In this case, the electromagnet can be activated in such a manner that it makes a magnetic field available and the motion element is attracted by the electromagnet. The motion element is accordingly moved in the direction of the electromagnet. Alternatively, the motion element may have been formed at least partly from a magnetic material. For instance, the motion element may include a permanent magnet. In this case, the electromagnet can be activated in such a manner that the motion element with the magnetic material is repelled by the electromagnet. Alternatively, there may also be provision that the motion element exhibits a further electromagnet. The electromagnet and the further electromagnet of the motion element can be energized in such a manner that they either mutually attract or mutually repel.

In accordance with the invention there is now provision that the electromagnet and the motion element are arranged relative to one another in such a manner that a predetermined spacing continues to exist between the electromagnet and the motion element when the motion element is moved. In other words, the drive device is designed in such a manner that the electromagnet and the motion element always exhibit a minimum spacing from one another. This holds for the case in which the motion element is located in a position of rest. In addition, this holds for the case in which the motion element is moved relative to the electromagnet. There is accordingly, in particular, no provision that in consequence of the activation of the electromagnet a magnetic circuit between the motion element and the electromagnet is closed and the electromagnet and the motion element exhibit a direct contact. This makes it possible, in particular, that the arrangement of the electromagnet relative to the motion element can be undertaken arbitrarily within predetermined limits. Consequently the available construction space, for instance, can be ideally utilized. Furthermore, in the interspace between the motion element and the electromagnet, in which the spacing continues to exist, additional elements can be arranged, by means of which the haptic feedback can be influenced. Hence a flexible arrangement of the electromagnet and of the motion element relative to one another can be made possible.

The drive device preferably includes an elastic element which can be deformed from a stable state into a metastable state by the motion of the motion element. In other words, the motion element may have been designed in the manner of a clicker. The elastic element may, for instance, have been formed from a spring steel that has been shaped in such a way that it is elastically deformed by the relative motion of the motion element in relation to the electromagnet. In this case, the motion element has preferably been formed at least partly from the magnetisable material, and in the course of the motion the motion element is attracted by the electromagnet. The elastic element, which is arranged between the electromagnet and the motion element, is elastically deformed by the motion of the motion element and consequently converted from the stable state into the metastable state. In this connection there is provision, in particular, that the motion element is connected to the operator element. By virtue of the configuration of the elastic element, the haptic feedback can be configured correspondingly. This results by virtue of the deformation of the elastic element. Consequently by virtue of the elastic element the haptic feedback can be adapted to the configuration of the operator element.

Moreover, it is advantageous if at least one damping element is arranged between the electromagnet and the motion element. This is suitable, in particular, for the configuration in which the motion element has been attracted by the electromagnet. The damping element may, for instance, have been formed from a rubber or from silicone. The thickness of the damping element in this case may have been chosen in such a way that it is larger than the spacing that continues to exist between the motion element and the electromagnet at least in the course of the motion. Consequently the motion of the motion element in the direction of the electromagnet is limited or damped by the damping element. Hence disturbing noises, for instance, that would arise when the motion element impinges on the electromagnet can be prevented.

In a further configuration, the operator apparatus exhibits a holding device, for holding the operator element, and at least one spring element, the operator element being resiliently supported in relation to the holding device by means of the at least one spring element. Consequently the operator element is supported on the holding device so as to be capable of being moved. This means that the operator element can be deflected from an initial position or rest position, for instance at the time of the operator input. With the at least one spring element, a restoring force can then be made available that is opposed to the force that is exerted on the operator element in the course of the operation. Consequently it can be ensured that the operator element returns to the initial position again. The spring element may, for instance, have been formed from a spring wire and may take the form of a helical spring. But the at least one spring element has preferably been manufactured from a damping material, for instance silicone.

In a further embodiment, the electromagnet is connected to the holding device, and the motion element can be moved relative to the electromagnet by the activation of the electromagnet. The electromagnet, which may include a coil, may, for instance, be held on the holding device by means of an appropriate screwed joint. In this case, the motion element can be moved relative to the electromagnet. For instance, there may be provision that the motion element is pressed against the operator element in consequence of the activation of the electromagnet.

In one embodiment, the motion element is connected to the operator element. In this case there may also be provision that an appropriate fastening element is arranged on the operator element, by means of which the motion element is held on the operator element. As already mentioned, the electromagnet is preferably held on the holding device. If the motion element is connected to the operator element, the motion element and consequently also the operator element which is connected to the motion element can be moved by the activation of the electromagnet. In this case, the drive device may have been designed in such a way that the motion element and consequently also the operator element are pulled in the direction of the electromagnet. By an appropriate activation of the electromagnet, a periodic motion of the motion element can then be brought about. Hence the motion element and the operator element, which is connected to the motion element, can be caused to execute mechanical oscillations or vibrations. In principle, the operator element can be caused to execute at least one mechanical oscillation by the motion of the motion element. There may also be provision that the operator element is caused to execute an oscillation that is composed of several frequencies.

In a further configuration, the motion element can be moved relative to the operator element, and the drive device is designed in such a manner that the motion element impinges on the operator element in the course of the motion. In this embodiment, the motion element is not connected to the operator element. The operator element in this case can be moved relative to the electromagnet and relative to the operator element. For instance, the motion element may be held in supported manner. In this case, the motion element has been formed, in particular, from a magnetic material, and the motion element is repelled by the electromagnet by the activation of the electromagnet. In this case, the electromagnet, the motion element and the operator element are arranged relative to one another in such a manner that the motion element impinges on the operator element in the course of the motion. In other words, the motion element is repelled by the electromagnet and strikes the operator element. Also in this way, a haptic feedback can be reliably output to the operator.

In a further embodiment, the motion element exhibits a plate element, which can be moved with the electromagnet, and at least one tappet connected to the plate element, which impinges on the operator element in the course of the motion of the plate element. The electromagnet may have been arranged to be stationary or immovable relative to the operator element. The plate element may, in particular, have been formed from a metal. The operator element may in this case have been arranged on a first side of the electromagnet, and the plate element may have been arranged on a second side, opposite the first side, of the electromagnet. The tappets may, for instance, have been arranged perpendicular to the principal direction of extent of the plate element and/or perpendicular to the principal direction of extent of the operator element. When the electromagnet is activated, the plate element can be pulled in the direction of the electromagnet. Hence the tappets are also accelerated and impinge on the operator element. Since the motion element has a relatively low mass, in consequence of the activation of the electromagnet the motion element can be accelerated correspondingly. Hence by virtue of the impinging of the tappets on the operator element a haptic feedback can be output that corresponds to a knocking.

In a further configuration, the motion element is resiliently supported. For this purpose a spring element, for instance, in the form of a helical spring may have been arranged in the respective tappets. By means of the respective spring elements, the motion element may have been resiliently supported on a carrier element or on a housing of the operator apparatus. Hence it can be guaranteed that the motion element is moved back again into its initial position in case the electromagnet is deactivated.

Moreover, it is advantageous if the motion element includes a base body which has been coated at least in some regions with a magnetisable material or with a magnetic material. In the case of the base body, it may be a question, for instance, of an electrically insulating material, in particular a synthetic material. This base body may have been coated with the magnetisable material or with the magnetic material on its external surface or on the surface facing towards the electromagnet. If the base body is manufactured from a synthetic material, for instance, and the magnetisable material or the magnetic material is applied as a coating, the motion element can be manufactured particularly inexpensively. In addition, a motion element that has a low weight can be made available. In this connection, experiments have shown that the weight of the motion element has a negative effect on the haptics, since the acceleration drops with increasing mass of the motion element.

In principle, there may also be provision that the motion element has been formed completely from the magnetisable material or from the magnetic material. For instance, the motion element may take the form of a plate. In this case, the plate may have been designed in such a way that it has a relatively small thickness. In this way, the motion element can be sufficiently accelerated, and consequently the haptic feedback can be output reliably.

In a further embodiment, the operator element includes an indicating device. Such an indicating device may be, for instance, a screen or a display. There may be provision that the operator apparatus includes a touch-sensitive screen or touchscreen. In this case, the capture device is constituted, for instance, by the touch-sensitive sensor of the touch-sensitive screen. With the aid of the indicating device, information can, in addition, be presented to the occupants of the motor vehicle.

A motor vehicle according to the invention includes an operator apparatus according to the invention. The motor vehicle takes the form, in particular, of a passenger car.

The preferred embodiments, presented with reference to the operator apparatus according to the invention, and the advantages thereof apply correspondingly to the motor vehicle according to the invention.

Further features of the invention arise from the claims, the figures and the description of the figures. The features and combinations of features stated above in the description, and also the features and combinations of features stated below in the description of the figures and/or shown in the figures alone can be used not only in the respectively specified combination but also in other combinations or on their own, without departing from the scope of the invention. Consequently, versions of the invention are also to be regarded as encompassed and disclosed that have not been explicitly shown and elucidated in the figures but that, by virtue of separate combinations of features, are evident from the elucidated versions and can be generated. Versions and combinations of features that consequently do not exhibit all the features of an originally formulated independent claim are also to be regarded as disclosed.

The invention will now be elucidated in more detail on the basis of preferred embodiment examples and also with reference to the appended drawings.

Shown in these drawings are:

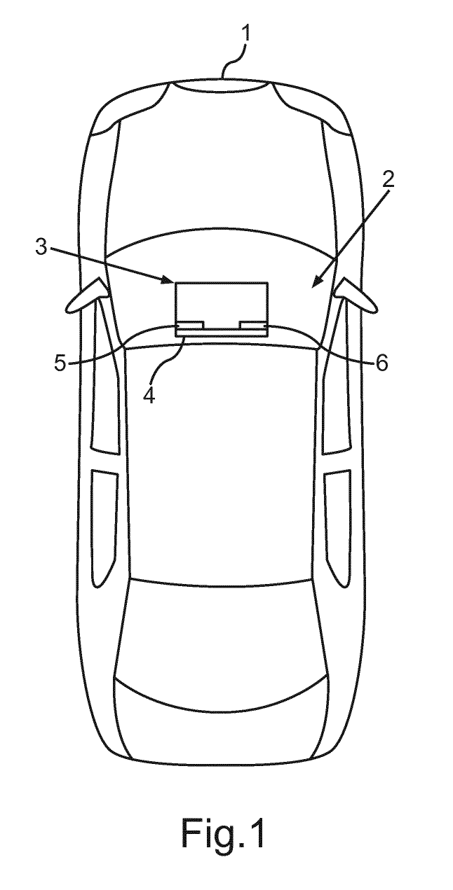

FIG. 1 a motor vehicle according to an embodiment of the present invention, which exhibits an operator apparatus;

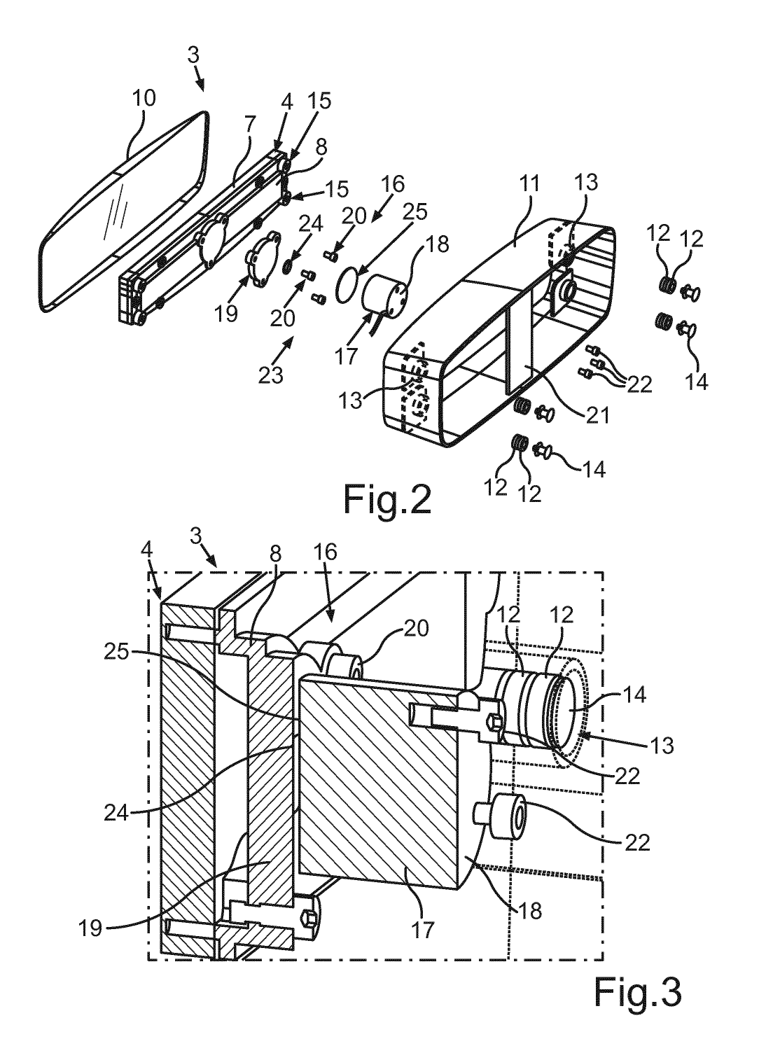

FIG. 2 the operator apparatus according to a first embodiment, in an exploded representation;

FIG. 3 the operator apparatus according to FIG. 2 in a sectional perspective view;

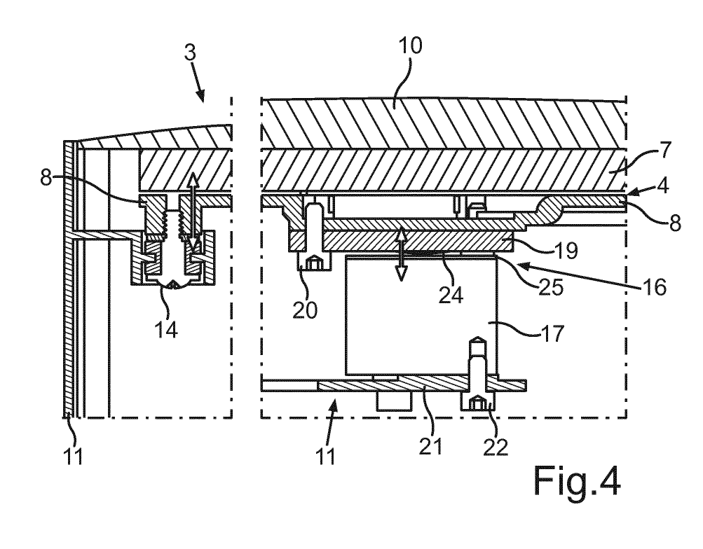

FIG. 4 the operator apparatus according to FIG. 2 in a sectional side view; and

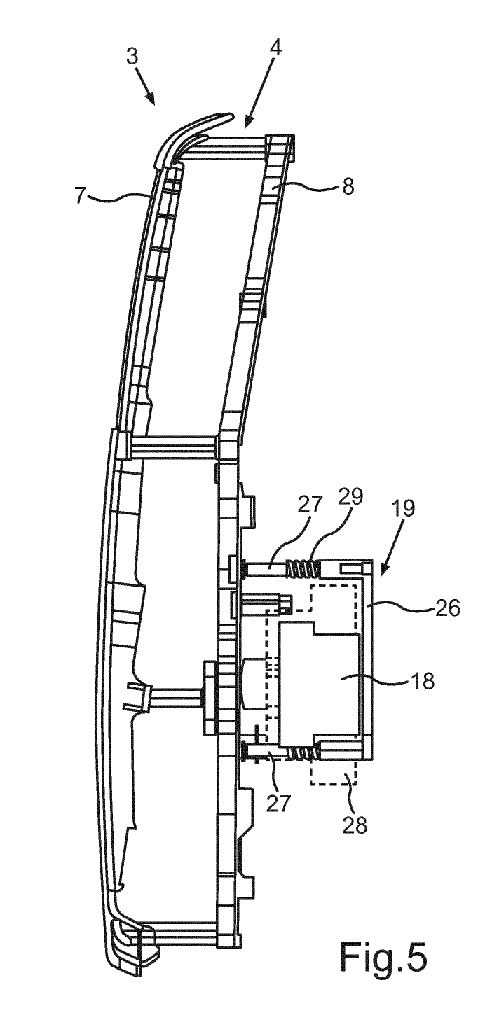

FIG. 5 the operator apparatus according to a second embodiment, in a sectional side view.

Identical and functionally identical elements in the figures are provided with the same reference symbols.

FIG. 1 shows a motor vehicle 1 according to an embodiment of the present invention, in a top view. The motor vehicle 1 in the present case takes the form of a passenger car. The motor vehicle 1 includes a passenger compartment 2 in which an operator apparatus 3 is arranged. The operator apparatus 3, which in the present case is represented schematically, includes an operator element 4 which can be operated by an occupant of the motor vehicle 1. In this case, the operator apparatus 3 may have been arranged in the passenger compartment 2 of the motor vehicle 1 in such a manner that the operator element 4 faces towards the occupant of the motor vehicle 1.

With the operator apparatus 3 an operator action in the form of the actuation of the operator element 4 can be captured. For this purpose the operator apparatus 3 exhibits a capture device 5. The capture device 5 may, for instance, include a touch-sensitive sensor. With this capture device 5, a contact with at least one finger or with an appropriate input unit on the operator interface 4, for instance, can be captured. In addition, with the capture device 5 the position of the contact on the operator element 4 can be detected. Furthermore, the operator apparatus 3 includes a drive device 6. By means of the drive device 6, the operator element 4 can be moved for the purpose of outputting a haptic feedback to the occupant or to the operator. In case the operator action or the touching of the operator element 4 is detected with the capture device 5, a corresponding control signal can be output to the drive device 6. In consequence of the control signal, the drive device 6 can then move the operator element 4.

FIG. 2 shows the operator apparatus 3 according to a first embodiment in an exploded representation. In this case, the operator element 4 includes an indicating device 7. The indicating device 7 may take the form of a screen, in particular a TFT (thin-film-transistor) screen. Furthermore, a holding plate 8 for holding the indicating device 7 is provided. In this case, the indicating device 7 is connected to the holding plate 8. In addition, the operator apparatus 3 includes a covering element 10 which, for instance, may have been formed from glass. The covering element 10 can be arranged on the indicating device 7 and serves for protection of the indicating device 7. In addition, the operator apparatus 3 includes a holding device 11. The holding device 11 serves for holding the operator element 4. In this case, the operator element 4 is resiliently supported on the holding device 11. For this purpose the operator apparatus 3 exhibits spring elements 12 which in the present case take the form of hollow cylinders and have been manufactured from an elastic material, in particular silicone. These spring elements 12 can be introduced into corresponding sockets 13 of the holding device 11. The spring elements 12 are held in the corresponding sockets 13 with appropriate fastening elements 14 which in the present case take the form of screws. In the present case, the fastening elements 14 or the screws are screwed into threads 15 on the holding plate 8.

In addition, the operator apparatus 3 includes a drive device 16. The drive device 16 includes an electromagnet 17 which may include a corresponding coil which is arranged in a housing 18. In addition, the drive device 16 includes a motion element 19. The motion element 19 may, in principle, have been formed from a magnetisable material or from a magnetic material. In the present case, the motion element 19 is substantially plate-shaped and has been manufactured from a magnetisable material. For instance, the motion element 19 has been formed from a metal. The motion element 19 can be fastened to the holding plate 8 of the operator element 4 with the aid of appropriate fastening elements 20 which in the present case take the form of screws. The electromagnet 17 is connected to the holding device 11. For this purpose the holding device 11 exhibits an appropriate crosspiece 21, on which the electromagnet 17 is held with appropriate fastening means 22 which take the form of screws.

During the operation of the drive device 16 the electromagnet 17 is activated appropriately. Accordingly, an electric current can be impressed into the coil of the electromagnet 17. Consequently, with the electromagnet 17 a magnetic field is made available, by which the motion element 19 is moved in the direction of the electromagnet 17. The motion element 19 is accordingly attracted by the electromagnet 17. Since the electromagnet 17 is connected to the holding device 11, and the motion element 19 is connected to the operator element 4, by the activation of the electromagnet 17 the operator element 4 can be moved relative to the holding device 11. By an appropriate activation, for instance a periodic activation, of the electromagnet 17, the operator element 4 can be caused to execute mechanical oscillations, in order to output a haptic feedback to the operator or to the occupant of the motor vehicle 1.

In an interspace 23 between the electromagnet 17 and the motion element 19 an elastic element 24 is arranged. The elastic element 24 is designed in the manner of a clicker and can be deformed between a stable state and a metastable state. The elastic element 24 may, for instance, have been formed from an appropriate metal sheet and may exhibit such a shape that it can be deformed between the stable state and the metastable state. When the motion element 19 is moved towards the electromagnet 17 in consequence of the magnetic field made available by the electromagnet 17, the elastic element 24 is deformed. In this case the elastic element 24 assumes the metastable state. If the coil of the electromagnet 17 is not energized—that is to say, no magnetic field is made available by the electromagnet 17—the motion element 19 moves away from the electromagnet 17 again, and the elastic element 24 returns to the stable state again. By virtue of this deformation of the elastic element 24, the haptic feedback which is output on the operator element 4 can be controlled appropriately. In addition, a damping element 25 is arranged between the electromagnet 17 and the motion element 19. The damping element 25 may be, for instance, a rubber mat. By virtue of the damping element 25, the motion of the motion element 19 in the direction of the electromagnet 17 is damped. Consequently, for instance, the motion element 19 can be prevented from striking against the electromagnet 17.

FIG. 3 shows the operator apparatus 3 according to FIG. 2 in a sectional perspective view. In this case, the operator apparatus 3 is shown in the assembled state. In this connection it can be discerned that the interspace 23 or an air gap has been formed between the motion element 19 and the electromagnet 17. In this case, the electromagnet 17 and the motion element 19 are arranged relative to one another in such a manner that also during the motion of the motion element 19 relative to the electromagnet 17 a minimum spacing always continues to exist between the electromagnet 17 and the motion element 19. Consequently the motion element 19 can be moved by means of the electromagnet 17 without a direct contact existing between the motion element 19 and the electromagnet 17 and consequently, for instance, a magnetic circuit being closed. By virtue of the fact that the minimum spacing or the interspace or the air gap between the electromagnet 17 and the motion element 19 is maintained, the elastic element 24 and the damping element 25 can be arranged between the electromagnet 17 and the motion element 19.

FIG. 4 shows the operator apparatus 3 according to FIG. 2 in a sectional side view. In this case, the spring elements 12 can be discerned which are arranged in the respective corresponding receptacles 13. In addition, the holding plate 8, on which the indicating device 7 is arranged, can be discerned which is resiliently supported on the holding device 11. In addition, the fastening of the motion element 19 to the holding plate 8 is shown. Furthermore, it can be discerned that the electromagnet 17 is fastened to the holding device 11 or, to be more exact, to the crosspiece 21.

FIG. 5 shows the operator apparatus 3 according to a second embodiment in a sectional side view. The electromagnet 18 is held in this case by means of a carrier element 28. This carrier element 28 may, for instance, have been fastened to a housing of the operator apparatus 3. Furthermore, the electromagnet 18 is connected to the holding plate 8. Here the motion element 19 exhibits a plate element 26 and a plurality of tappets 27 which are connected to the plate element 26. In this case, the plate element 26 is arranged in such a way that the plate element 26 is located on a first side of the electromagnet 18 and the operator element 4 is located on a second side, opposite the first side, of the electromagnet 18. The motion element 19 may, for instance, exhibit three tappets 27, two of which can be discerned in the present view. The plate element 26 may, for instance, have been formed from a metal.

When the electromagnet 18 is activated, the plate element 26 is moved in the direction of the electromagnet 18. As a result, the tappets 27 are accelerated in the direction of the operator element 4 and impinge on the operator element 4 or on the holding plate 8. Since the motion element 19 in this embodiment has a low mass, it can be accelerated effectively by means of the electromagnet 18. Hence a haptic feedback can be made available that corresponds to a knocking. Furthermore, spring elements 29 are provided, by means of which the motion element 19 is resiliently supported on the carrier element 28. By means of the spring element 29, it can be made possible that the motion element 19 is moved back again into the initial position or rest position.

1. An operator apparatus for a motor vehicle (1), with an operator element (4), with a capture device (5) for capturing an operator input carried out on the operator element (4), and with a drive device (6), by means of which the operator element (4) can be moved, in a manner depending on the operator input captured with the capture device (5), for the purpose of outputting a haptic feedback, wherein the drive device (6) exhibits an electromagnet (17) and a motion element (19) which can be moved by an activation of the electromagnet (17), characterized in that the electromagnet (17) and the motion element (19) are arranged relative to one another in such a manner that a predetermined spacing continues to exist between the electromagnet (17) and the motion element (19) when the motion element (19) is moved.

2. The operator apparatus according to claim 1, wherein the drive device includes an elastic element configured to be deformed from a stable state into a metastable state by the motion of the motion element.

3. The operator apparatus according to claim 1, wherein at least one damping element is arranged between the electromagnet and the motion element.

4. The operator apparatus according to claim 1, wherein the operator apparatus exhibits a holding device, for holding the operator element, and at least one spring element, the operator element being resiliently supported in relation to the holding device by means of the at least one spring element.

5. The operator apparatus according to claim 4, wherein the electromagnet is connected to the holding device, and the motion element can be moved relative to the electromagnet by the activation of the electromagnet.

6. The operator apparatus according to claim 1, wherein the motion element is connected to the operator element.

7. The operator apparatus according to claim 1, wherein the motion element can be moved relative to the operator element, and the drive device is such that the motion element impinges on the operator element in the course of the motion.

8. The operator apparatus according to claim 7, wherein the motion element exhibits a plate element, which moves with the electromagnet, and at least one tappet connected to the plate element, which impinges on the operator element in the course of the motion of the plate element.

9. The operator apparatus according to claim 7, wherein the motion element is resiliently supported.

10. The operator apparatus according to claim 1, wherein the motion element includes a base body which has been coated at least in some regions with a magnetisable material or with a magnetic material.

11. The operator apparatus according to claim 1, wherein the operator element includes an indicating device.

12. A motor vehicle with an operator apparatus according to claim 1.
